(19) United States
(12) Patent Application Publication
(10) Pub. No.: US 2003/0181059 A1
(43) Pub. Date: Sep. 25, 2003

(54) Method for fabricating pad oxide layer in semiconductor integrated circuits

(76) Inventors: Liang-Tien Huang, Hsinchu (TW); Hsin-Yi Chen, Junghe City (TW); Chung-Chi Chang, Hsinchu (TW)

Correspondence Address: J.C. Patents, Inc., Suite 250, 4 Venture, Irvine, CA, 92618, US

(21) Appl. No.: 10/128,743

(22) Filed: Apr. 23, 2002

(30) Foreign Application Priority Data
Mar. 20, 2002 (TW) 91105277

(51) Int. Cl. H01L 21/302; H01L 21/461

(52) U.S. Cl. 438/733; 438/689

(57) ABSTRACT

A method for fabricating a pad oxide layer in integrate circuits is described. A zero oxide layer is formed on a silicon wafer, wherein a thickness of the zero oxide layer is slightly greater than the desired thickness of a pad oxide layer that is required in a subsequent process. Photolithography and etching are further conducted to pattern the zero oxide layer and the silicon wafer to form a plurality of alignment marks on the silicon wafer. A cleaning process is further conducted to remove the photoresist layer and a portion of the zero oxide layer to prevent photoresist debris remaining and to control the thickness of the zero oxide layer such that the thickness of the zero oxide layer is same as the desired thickness of the pad oxide layer that is needed in the subsequent process.

### CROSS-REFERENCE TO RELATED APPLICATION

This application claims the priority benefit of Taiwan application serial no. 91105277, filed Mar. 20, 2002.

### BACKGROUND OF THE INVENTION

1. Field of the Invention

The present invention relates to a semiconductor fabrication process. More particularly, the present invention relates to a method for fabricating a pad oxide layer in semiconductor integrated circuit.

2. Background of the Invention

The semiconductor manufacturing process becomes more and more difficult as integration increases and device dimension continues to decrease. Measuring means are needed to monitor the manufacturing process to promptly reflect any problem, which may result in manufacturing errors and in production loss.

The photolithography process is an essential process step in the manufacturing of semiconductor devices. The various patterns and doped regions or related structures of a MOS device is determined by the photolithography process. Beside the critical dimension (CD), the precision of alignment is another factor that controls the success of a photolithography process being performed on a silicon wafer. In order to achieve the alignment effect, before the photolithography process is performed, a pattern is etched on the silicon wafer as alignment marks, which are going to be used in subsequent exposures of the various layers.

The conventional fabrication method for alignment marks includes forming a zero oxide layer on a silicon wafer, wherein the zero oxide layer is used to prevent the wafer from being contaminated by a subsequently formed photoresist. According to a typical photolithography process, a photoresist is formed on the zero oxide layer, followed by performing exposure and development processes to pattern the photoresist layer. Using the photoresist as a mask, the zero oxide layer and the wafer are etched to form the alignment marks. The photoresist layer is eventually removed.

After the formation of the alignment marks is completed, a pad oxide layer and a nitride layer are usually formed on the silicon wafer, followed by performing the shallow trench isolation (STI) manufacturing or the local oxidation manufacturing. Since the thickness ratio of the pad oxide layer to the nitride layer is fixed, the thickness of the pad oxide layer can vary to accommodate the nitride layer according to the manufacturing process or product that is being formed. Therefore, between the formation of the alignment marks and the formation of the pad oxide layer, a process for forming a zero oxide layer and a cleaning process to remove the zero oxide layer using hydrogen fluoride type of toxic solutions are required. The manufacturing cost and the product cycle time thus greatly increased.

### SUMMARY OF THE INVENTION

The present invention provides a method to fabricate a pad oxide layer in semiconductor integrated circuits, whereby the pad oxide layer and the zero oxide layer are integrally formed.

The present invention provides a method for fabricating a pad oxide layer in semiconductor integrated circuits, wherein fabricating an extra oxide layer as in the prior art is prevented to lower the processing time.

The present invention provides a fabrication method for a pad oxide layer in semiconductor integrated circuits, wherein the production cost is reduced.

The present invention provides a method to fabricate a pad oxide layer in semiconductor integrated circuits, which includes forming a zero oxide layer on a silicon wafer. The zero oxide layer has a thickness greater than the desired thickness of a pad oxide that is going to be formed subsequently. A photoresist is formed on the zero oxide layer. Photolithography is performed to pattern the photoresist layer, exposing a part of the zero oxide layer. The exposed zero oxide layer is then removed by etching until the silicon wafer is exposed. The exposed silicon wafer is further removed to form a plurality of alignment marks. A cleaning process is used to remove the photoresist layer. The cleaning process is continued until a portion of the zero oxide layer is removed to prevent any photoresist debris remaining and to control the thickness of the zero oxide layer to the desired thickness of a subsequently formed pad oxide layer. The process step in forming the pad oxide layer can be omitted by using the remaining of the zero oxide layer as the pad oxide layer.

Accordingly, by integrating the manufacturing of the zero oxide layer and the pad oxide layer, an additional oxide layer manufacturing step as in the prior art is precluded to reduce the product cycle time and to reduce the manufacturing cost.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow diagram illustrating the method for fabricating a pad oxide layer in semiconductor integrated circuits according to a preferred embodiment of the present invention.

FIG. 2 is a schematic diagram in a cross-sectional view illustrating the manufacturing of alignment marks on a silicon wafer during the fabrication of a pad oxide layer in semiconductor integrate circuits according to the preferred embodiment of the present invention.

FIGS. 3A to 3E are schematic diagrams along the III-III cross-section of the silicon wafer in FIG. 2 illustrating the process flow of the method according to the preferred embodiment of the present invention.

### DESCRIPTION OF THE PREFERRED EMBODIMENTS

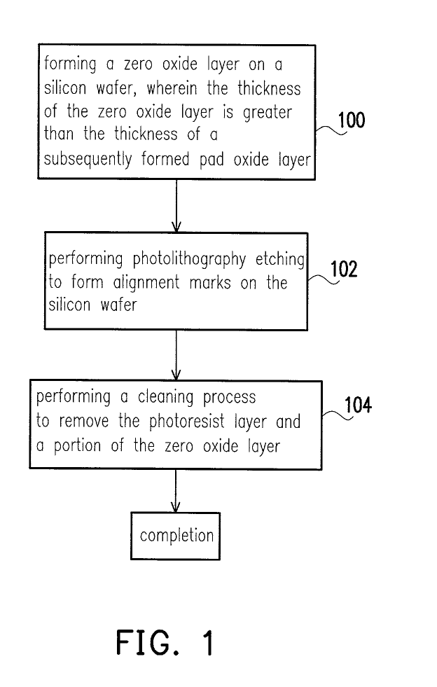

FIG. 1 is a flow diagram illustrating the method for fabricating a pad oxide layer in semiconductor integrated circuits according to a preferred embodiment of the present invention.

As shown in FIG. 1, the desired thickness for the pad oxide needs to be known in advance according to the present invention. In step 100, a zero oxide layer is formed on a silicon wafer, wherein the thickness of the zero oxide layer is controlled to be greater than the desired thickness of a pad oxide layer that is going to be formed subsequently. The difference in thickness between the zero oxide layer and the pad oxide layer is determined by the subsequently performed cleaning process, which in turns determined by those skilled in the art according to the various semiconductor manufacturing. For example, the predetermined thickness of the pad oxide layer is 70 angstroms, the thickness of the zero oxide layer can be 100 angstroms.

Thereafter, as indicated in step 102, photolithography and etching are conducted to form a plurality of alignment marks on the silicon wafer. The photolithography and etching are conducted by forming a photoresist on the zero oxide layer, followed by performing exposure and development processes to pattern the photoresist, exposing a portion of the zero oxide layer. Using the patterned photoresist layer as a mask, the exposed portion of the zero oxide layer is etched to expose a portion of the wafer. The exposed portion of the wafer is further etched to form a plurality of alignment marks.

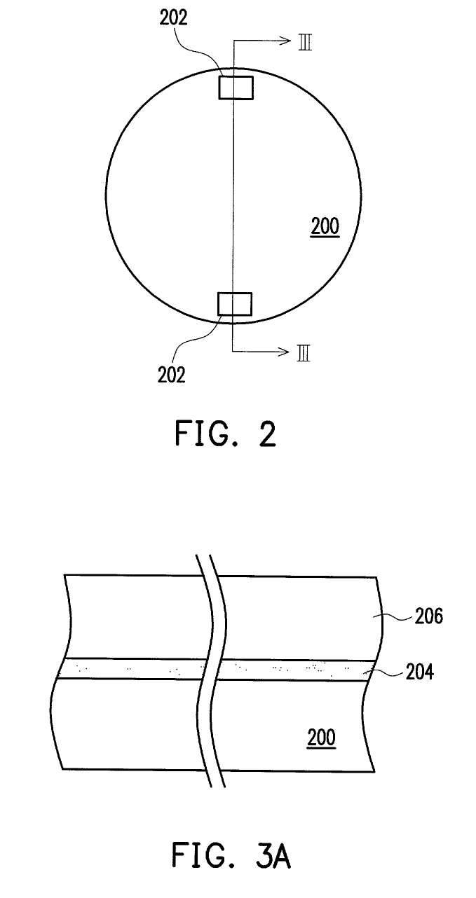

As shown in step 104, a cleaning process is conducted to remove the photoresist layer and a portion of the zero oxide layer. Any chemical agent that can remove the photoresist layer can be used in the cleaning process, for example, the standard clean 1 solution (SC1) that comprises ammonium hydroxide (NH₄OH), hydrogen peroxide (H₂O₂) and deionized water. Moreover, removing the portion of the zero oxide layer is finely controlled until the thickness of the zero oxide layer is about the same as the desired thickness of a pad oxide layer in order to achieve integrating the formation of a pad oxide layer and a zero oxide layer according to the present invention. The subsequent process is continued according the various types of manufacturing, which is well known to those skilled in the art. For further clarification of the position of the alignment marks on the wafer, refer to FIG. 2.

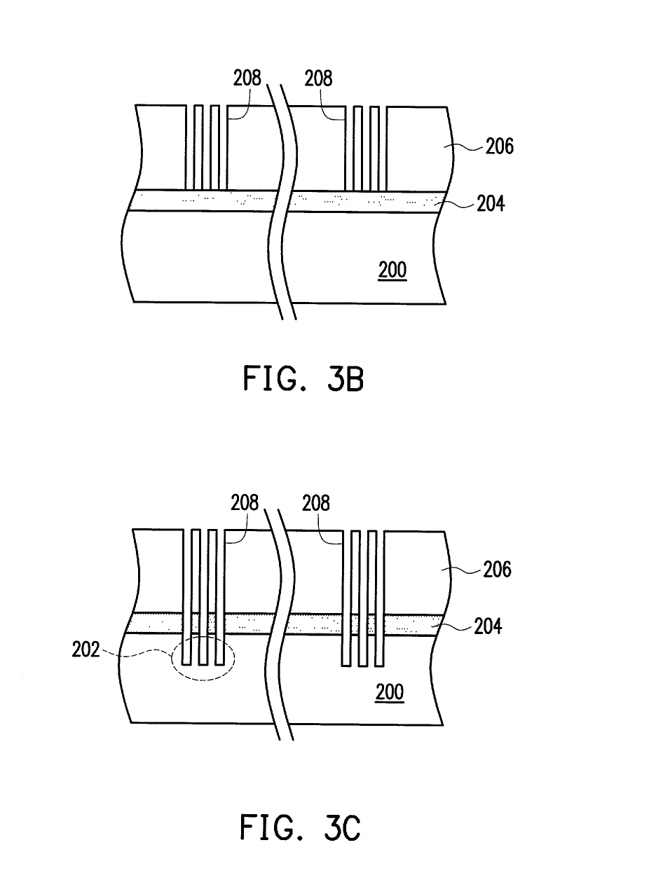

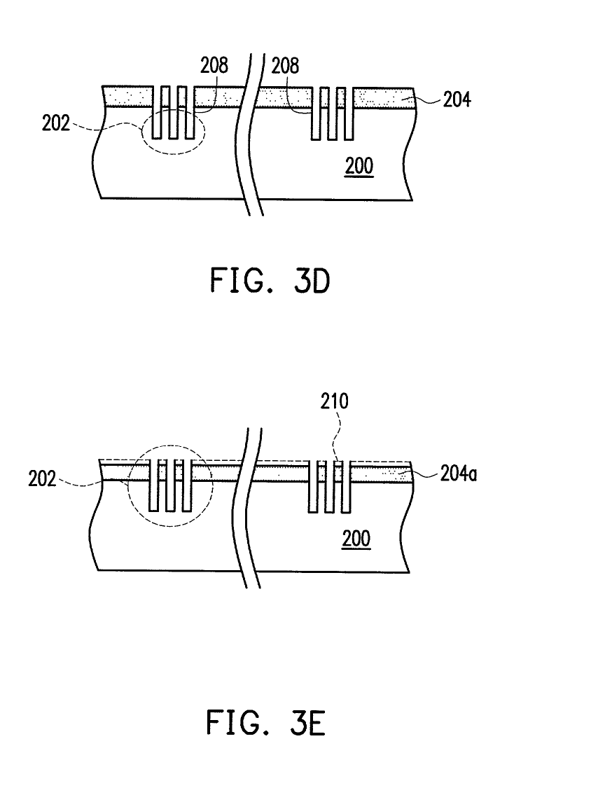

FIG. 2 is a schematic diagram in a cross-sectional view illustrating the manufacturing of a plurality of alignment marks on a silicon wafer during the fabrication of a pad oxide layer in semiconductor integrated circuits according to the preferred embodiment of the present invention. The position of the alignment marks 202 is shown in FIG. 2, in which the alignment marks 202 are located opposite from each other along the circumference of the wafer 200 or the alignment marks are placed at fixed positions according to the setting of the alignment detection machine. The pattern for the alignment marks can be changed and is not limited to the pattern as shown in FIG. 2. Using the pattern in FIG. 2 as an example, the manufacturing of alignment marks is illustrated from FIGS. 3A to 3E.

As shown in FIG. 3A, a zero oxide layer is formed on the silicon wafer 200, wherein the thickness of the zero oxide layer 204 is greater than that of a subsequently formed pad oxide layer. The difference in the thickness between the zero oxide layer 204 and the pad oxide layer is determined by the subsequently performed cleaning process, which is turns is determined by one skilled in the art according to the various semiconductor processes that going to be performed. For example, when the pad oxide layer is about 70 angstroms, the zero oxide layer 204 is about 100 angstroms. A photoresist 206 is then formed on the zero oxide layer 204, wherein the zero oxide layer 204 is to prevent the silicon wafer from being contaminated by the photoresist 206.

Continuing to FIG. 3B, the photoresist 206 is patterned to form a plurality of patterns 208 by the exposure and development processes. A portion of the zero oxide layer 204 is also exposed. The patterns 208 include some openings. The patterns 208 are not limited to those illustrated in FIG. 3B.

Referring to FIG. 3C, an etching process is conducted to expose a portion of the zero oxide layer 204 until the silicon wafer 200 is exposed. The exposed silicon wafer 200 is also etched to form a plurality of alignment marks 202 on the silicon wafer 200.

Referring to FIG. 3D, a cleaning process is conducted to remove the remaining of the photoresist 206. Since photoresist debris still remains on the zero oxide layer 204, the cleaning process is continued to remove the debris.

Referring to FIG. 3E, the cleaning process is continued until a portion of the top part of the zero oxide layer 204 is removed. The thickness of the zero oxide layer 204 is controlled to about the same as the desired thickness of a pad oxide layer that needs to be formed subsequently. Not only the photoresist debris can be completely removed, the manufacturing of a pad oxide layer can be skipped by using the remaining of the zero oxide layer 204a as the pad oxide layer. It is not necessary to use hydrogen fluoride for the oxide layer removal in the cleaning process. Any chemical agent like SCI that can remove photoresist is acceptable.

Since by controlling the thickness of the zero oxide layer to be greater than that of a subsequently formed pad oxide layer and coordinating the thickness of the zero oxide layer with the cleaning process for cleaning the photoresist debris, the zero oxide layer and the pad oxide layer can be integrally formed.

Since according to the present invention, the formation of the pad oxide layer is integrated with the formation of the zero oxide layer, forming an additional oxide layer as in the prior art, leading to a reduction in the process cycle time is prevented.

Moreover, the present invention precludes a formation and then a removal of an oxide layer, the manufacturing cost is reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a pad oxide layer having a first thickness in semiconductor integrated circuits, the method comprising:
forming a zero oxide layer that has a second thickness greater than the first thickness on a silicon wafer;
performing a photolithography process and an etching process to form a plurality of alignment marks on the silicon wafer; and
performing a cleaning process to remove a portion of the zero oxide layer such that a thickness of the remaining zero oxide layer is about equal to the first thickness.

2. The method of claim 1, wherein performing the photolithography process and the etching process to form the plurality of the alignment marks on the silicon wafer further comprises:
forming a photoresist layer on the zero oxide layer;
patterning the photoresist layer to expose a portion of the zero oxide layer; and
etching the exposed portion of the zero oxide layer and the substrate to form the alignment marks using the patterned photoresist as a mask.

3. The method of claim 2, wherein the cleaning process further includes removing the photoresist layer.

4. A method to fabricate a pad oxide layer having a first thickness in semiconductor integrated circuits, the method comprising:
forming a zero oxide layer that has a second thickness greater that the first thickness on a silicon wafer;
forming a photoresist layer on the zero oxide layer;
patterning the photoresist layer by an exposure process and a development process to form a plurality of patterns which expose a portion of the zero oxide layer;
performing an etching process to remove the exposed portion of the zero oxide layer until the silicon wafer is exposed using the photoresist layer as a mask;
etching the exposed silicon wafer to form a plurality of alignment marks on the silicon wafer using the photoresist layer as the mask; and
performing a cleaning process to remove the photoresist layer and a portion of the zero oxide layer such that a thickness of a remaining zero oxide layer is equal to the first thickness.

5. The method of claim 4, wherein the cleaning process uses a cleaning agent comprises a SC1 solution.
